(19) United States
(12) Patent Application Publication
(10) Pub. No.: US 2018/0076150 A1
(43) Pub. Date: Mar. 15, 2018

(54) SEMICONDUCTOR CHIP, SEMICONDUCTOR APPARATUS, SEMICONDUCTOR WAFER, AND SEMICONDUCTOR WAFER DICING METHOD

(71) Applicant: SII Semiconductor Corporation, Chiba-shi (JP)

(72) Inventor: Hiroyuki UTSUNOMIYA, Chiba-shi (JP)

(21) Appl. No.: 15/695,357

(22) Filed: Sep. 5, 2017

(30) Foreign Application Priority Data
Sep. 13, 2016 (JP) 2016-178468

(51) Int. Cl. H01L 23/00; H01L 23/544; H01L 23/58; H01L 21/78

(52) U.S. Cl. CPC H01L 23/562; H01L 23/544; H01L 23/585; H01L 23/49541; H01L 21/78; H01L 2223/5446; H01L 23/564

(57) ABSTRACT

Provided are a semiconductor chip, a semiconductor apparatus, a semiconductor wafer, and a semiconductor wafer dicing method in which chipping is prevented while securing an effective region of the semiconductor chip to have a sufficient area. Each semiconductor chip region which becomes a semiconductor chip has a rectangular shape, and includes non-effective regions in which no circuit device is placed. The non-effective regions are provided only at two corner portions located at two ends of an arbitrary side of the rectangular shape. The semiconductor wafer has a plurality of semiconductor chip regions arranged so that all non-effective regions face the traveling direction of a dicing blade in a second dicing step.

### BACKGROUND OF THE INVENTION

### 1. Field of the Invention

The present invention relates to a semiconductor chip, a semiconductor apparatus, a semiconductor wafer, and a semiconductor wafer dicing method.

### 2. Description of the Related Art

A semiconductor wafer is, generally, divided into individual semiconductor chips by dicing a semiconductor wafer on which a plurality of semiconductor chip regions and a plurality of dicing lines are formed and aligned longitudinally and laterally along the dicing lines.

It is known that corner portions of semiconductor chips are susceptible to cracks or chipping (herein after collectively referred to as chipping) in the dicing step.

As a method of preventing chipping, in Japanese Patent Application Laid-open No. 2009-99681, there is proposed forming a through hole at each intersection point between dicing lines before a semiconductor wafer is diced into individual pieces, to chamfer the four corner portions of each semiconductor chip that is a resultant individual piece.

In the method of Japanese Patent Application Laid-open No. 2009-99681 in which all corners of a semiconductor chip are chamfered at an intersection point between dicing lines, however, the chamfered portions are non-effective regions (regions in which a circuit device is not/cannot be placed), and thus make an effective region (a region in which a circuit device is placed) in the semiconductor chip smaller. This means that increase in the chip size is needs in order to secure a necessary effective region.

### SUMMARY OF THE INVENTION

It is an object of the present invention to provide a semiconductor chip, a semiconductor apparatus, a semiconductor wafer, and a semiconductor wafer dicing method in which chipping is prevented while securing a necessary effective region of the semiconductor chip.

According to one embodiment of the present invention, there is provided a semiconductor chip having a rectangular shape and including: non-effective regions in which no circuit device is placed, the non-effective regions being provided only at two corner portions that are located at two ends of one arbitrary side out of the four sides; and an effective region in which a circuit device is placed, the effective region being provided in a remaining region other than the non-effective regions.

Further, according to one embodiment of the present invention, there is provided a semiconductor wafer including a plurality of semiconductor chip regions and a plurality of dicing lines that are alternated and aligned in a first direction and a second direction, which is perpendicular to the first direction, in which each of the plurality of semiconductor chip regions has a rectangular shape and includes non-effective regions and an effective region, the non-effective regions being provided only at two corner portions that are located at two ends of one side along the first direction, the non-effective regions including no circuit device, the effective region being provided in a remaining region other than the non-effective regions, the effective region including a circuit device, in which the one side of each of the plurality of semiconductor chip regions is on the same straight line as the one side of each of other semiconductor chip regions that are aligned in the same row as the semiconductor chip region of interest in the first direction, and in which the non-effective regions are equally spaced from one another in the second direction.

Still further, according to one embodiment of the present invention, there is provided a semiconductor wafer dicing method including: a step of preparing a semiconductor wafer on which a plurality of semiconductor chip regions and a plurality of dicing lines are alternated and aligned longitudinally and laterally; a first dicing step of dicing the semiconductor wafer into strips along dicing lines that run in a first direction out of the plurality of dicing lines, by using a dicing blade; and a second dicing step of dicing the semiconductor wafer into a plurality of individual semiconductor chips along dicing lines that run in a second direction perpendicular to the first direction out of the plurality of dicing lines, by using the dicing blade, in which each of the plurality of semiconductor chip regions has a rectangular shape and includes non-effective regions and an effective region, the non-effective regions being provided only at two corner portions that face a traveling direction of the dicing blade in the second dicing step, the non-effective regions including no circuit device, the effective region being provided in a remaining region other than the non-effective regions, the effective region including a circuit device.

According to the present invention, non-effective regions are provided only at two corner portions located at both ends of one side of each semiconductor chip region that are corner portions facing the traveling direction of the dicing blade, instead of providing non-effective regions at all four corners of each semiconductor chip region. The present invention is thus capable of preventing chipping, and also using the remaining two corner portions as an effective region. The chip size can therefore be kept small.

### BRIEF DESCRIPTION OF THE DRAWINGS

FIG. 1 is a partial enlarged view of a semiconductor wafer according to a first embodiment of the present invention.

FIG. 2 is a partial enlarged view for illustrating a dicing step in which the semiconductor wafer of FIG. 1 is diced.

FIG. 3 is a partial enlarged view of a semiconductor wafer according to a second embodiment of the present invention.

FIG. 4A, FIG. 4B, and FIG. 4C are sectional views for illustrating crack stopper regions of FIG. 3.

FIG. 5A, FIG. 5B, and FIG. 5C are partial enlarged views for illustrating another example of non-effective regions in the embodiments of the present invention.

FIG. 6 is a schematic plan view for illustrating a semiconductor apparatus in which a semiconductor chip that is one of individual pieces created by dicing a semiconductor wafer in the embodiments of the present invention is mounted and sealed with resin.

FIG. 7 is a partial enlarged view for illustrating a modification example of the semiconductor wafer according to the second embodiment of the present invention.

FIG. 8A, FIG. 8B, and FIG. 8C are views for illustrating a common method of dividing a semiconductor wafer into individual semiconductor chips.

FIG. 9 is a view for illustrating the common method of dividing a semiconductor wafer into individual semiconductor chips.

FIG. 10 is a view for illustrating the common method of dividing a semiconductor wafer into individual semiconductor chips.

FIG. 11 is a view for illustrating a problem that arises in the common method of dividing a semiconductor wafer into individual semiconductor chips.

### DESCRIPTION OF THE EMBODIMENTS

Before a description on embodiments of the present invention is given, how the inventor of the present invention has thought of the present invention is described.

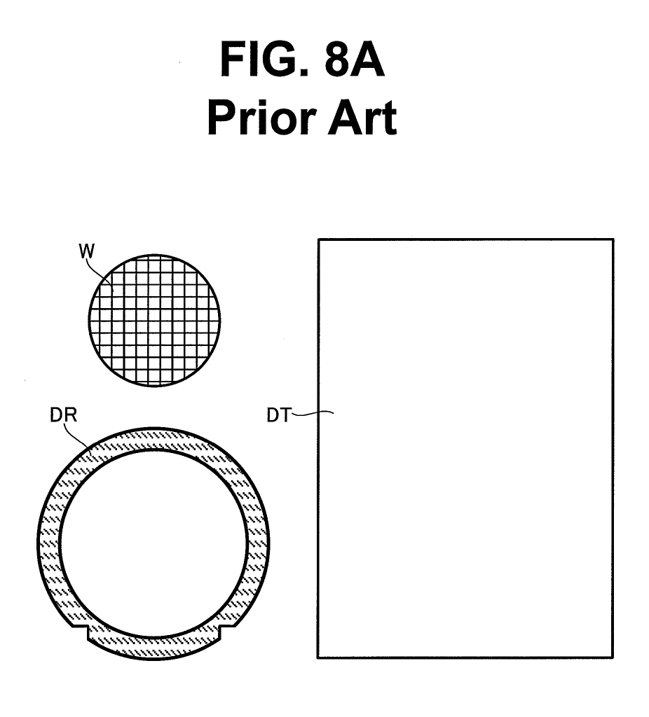

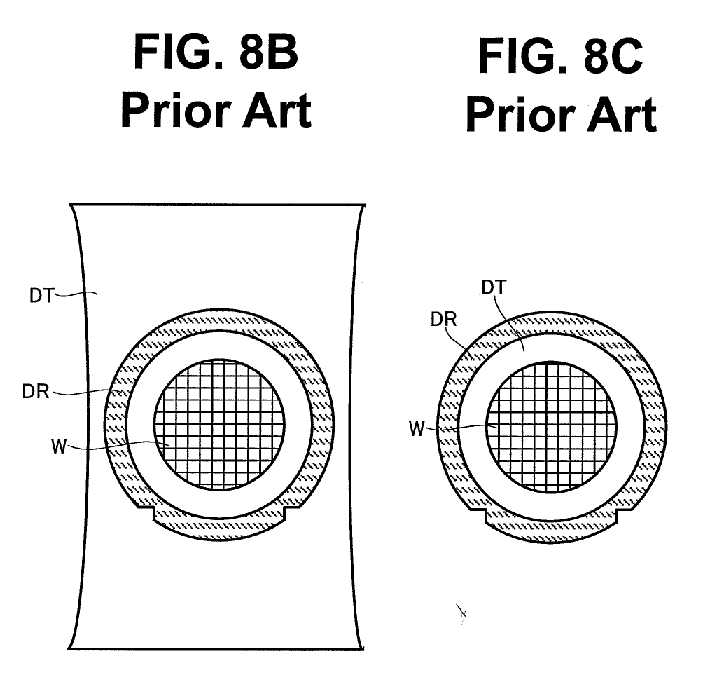

FIG. 8A to FIG. 10 are views for illustrating a general method of dividing a semiconductor wafer (semiconductor substrate) into individual semiconductor chips.

First, a semiconductor wafer W on which devices are formed, a dicing ring DR, and a piece of dicing tape DT are prepared as illustrated in FIG. 8A.

Next, the dicing ring DR and the semiconductor wafer W are stuck onto the dicing tape DT as illustrated in FIG. 8B. It is important to stick the dicing ring DR and the semiconductor wafer W evenly without forming air bubbles therebetween. This can be accomplished by sticking the semiconductor wafer W while applying tension to the dicing tape DT in the manner illustrated in FIG. 8B.

Thereafter, the dicing tape DT around the dicing ring DR is removed to obtain the dicing ring DR and the semiconductor wafer W that are stuck onto a portion of the dicing tape DT as illustrated in FIG. 8C, and this is set in a dicing apparatus (not shown).

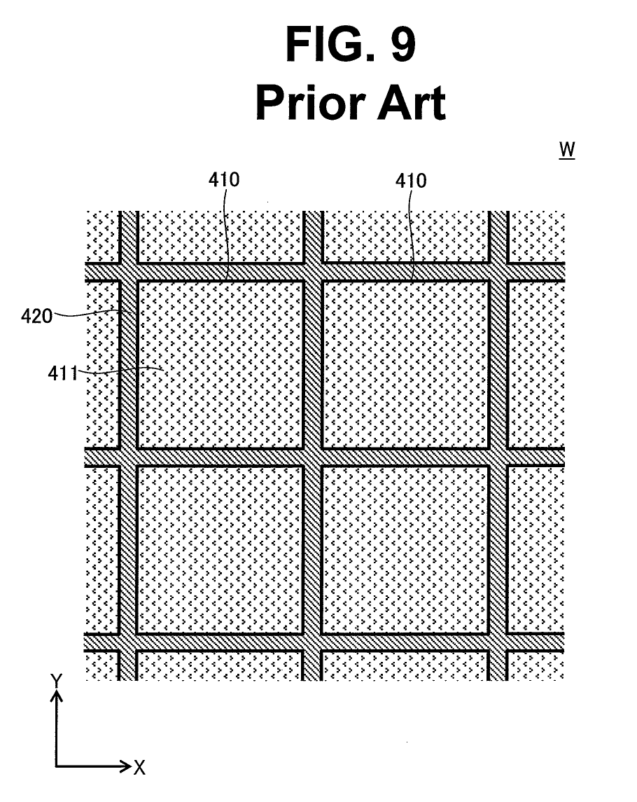

FIG. 9 is a partial enlarged view of the semiconductor wafer W that is stuck onto the dicing tape DT for dicing. A plurality of semiconductor chip regions 410 and dicing lines 420 along which the semiconductor chip regions 410 are diced into individual chips are formed on the semiconductor wafer W of FIG. 9. An effective region in each semiconductor chip region 410 is denoted by a reference symbol 411. The entire semiconductor chip region 410 is, thus, an effective region (a region in which a circuit device is placed) in this example.

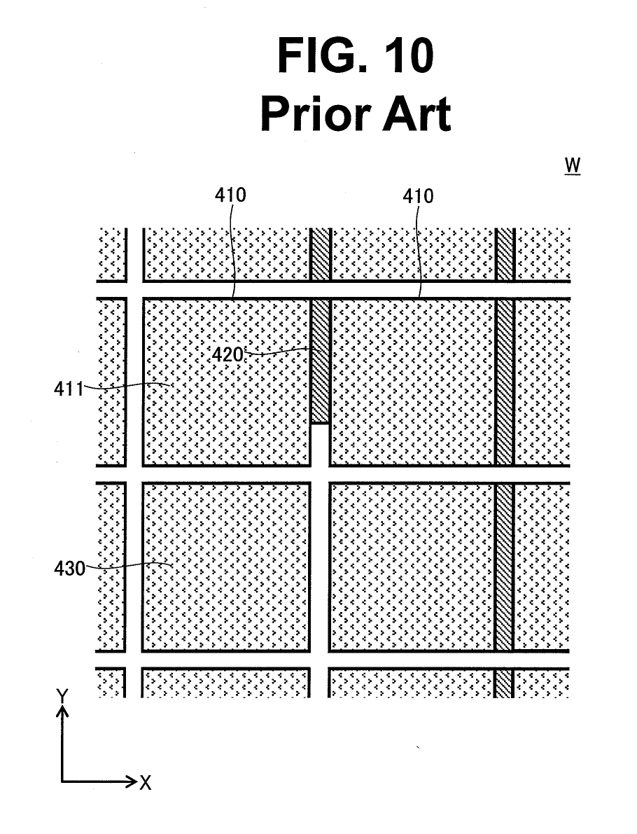

The middle of a dicing step (dicing into individual pieces) in which the semiconductor wafer W is diced halfway is illustrated in FIG. 10.

In the step of dicing the semiconductor wafer W, a dicing blade (not shown) first divides the semiconductor wafer W into strips by cutting the semiconductor wafer W in an X direction along the dicing lines 420 in order (hereinafter also referred to as “first dicing step”). The dicing blade next cuts the semiconductor wafer w that is now strips in a Y direction along the dicing lines 420 in order (hereinafter also referred to as “second dicing step”). The semiconductor wafer W can be divided into individual semiconductor chips 430 by cutting the semiconductor wafer W along all of the dicing lines 420 in this manner. An outlined white portion in FIG. 10 represents a portion in which the cutting is completed.

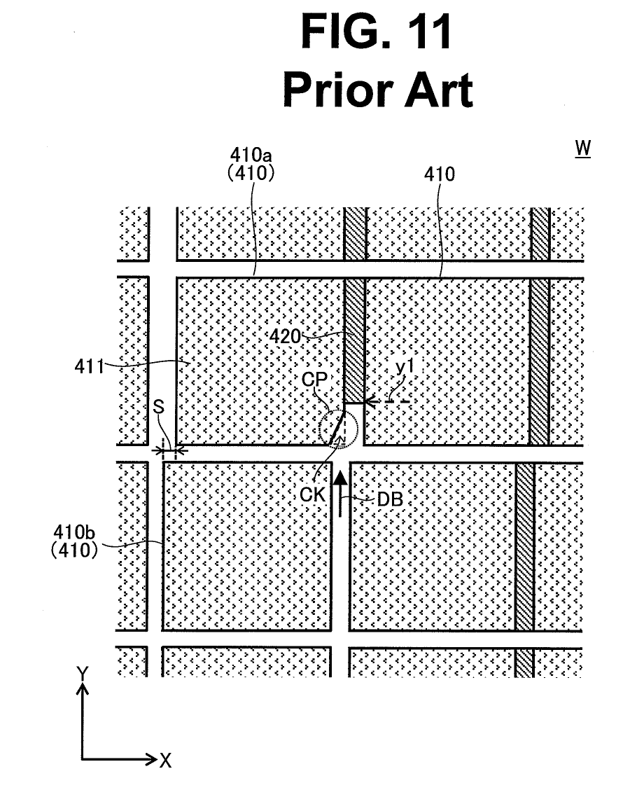

However, a problem illustrated in FIG. 11 may occur in the above-mentioned method of dicing a semiconductor wafer into individual pieces.

In FIG. 11, the first dicing step is complete and the second dicing step is in progress (cutting has progressed to a point indicated by the broken line arrow y1 in FIG. 11).

Applying tension to the dicing tape DT as described above with reference to FIG. 8B, the semiconductor wafer W is stuck onto the dicing tape DT. The tension on the dicing tape DT is, thus, released as the cutting of the semiconductor wafer W advances, thereby causing a phenomenon in which the separated regions of the semiconductor wafer W shift around during dicing.

Specifically, a shift S tends to occur between the semiconductor chip regions 410 that are adjacent to each other in the Y direction after the first dicing step finishes as illustrated in FIG. 11. A case in which a semiconductor chip region 410a shifts in the X direction (the rightward direction in FIG. 11) with respect to a semiconductor chip region 410b is illustrated in FIG. 11 as an example.

The shift S causes the dicing blade advancing in the direction of an arrow DB to bump into a corner portion CP of the semiconductor chip region 410a which is surrounded by a dotted line. A crack CK or chipping occurs in the corner portion CP as a result.

It is thus understood that chipping occurs due to a shift made between the semiconductor chip regions 410 in the traveling direction of the dicing blade (the Y direction) in the second dicing step.

The present invention has been made based on above knowledge.

Now, the embodiments of the present invention are described with reference to the drawings.

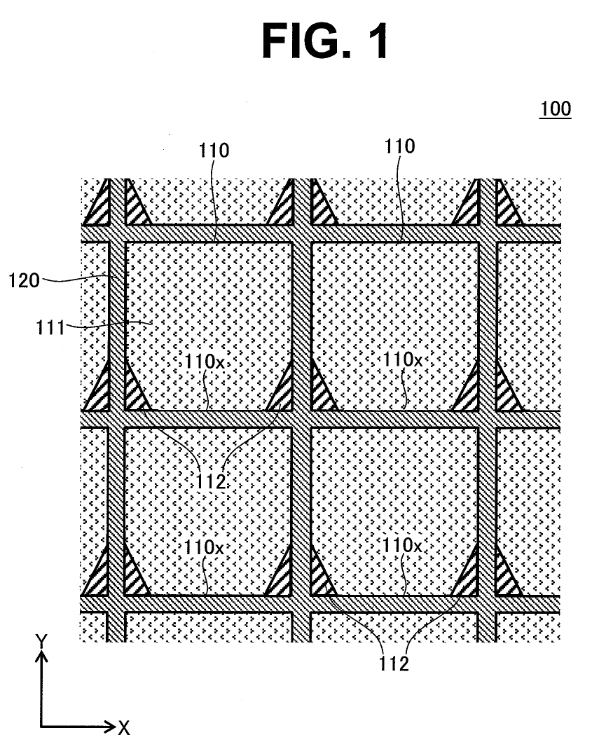

FIG. 1 is a partial enlarged view of a semiconductor wafer 100 according to a first embodiment of the present invention.

On the semiconductor wafer 100, a plurality of semiconductor chip regions 110 and a plurality of dicing lines 120 are formed in an alternating manner, and are aligned in an X direction (hereinafter also referred to as “first direction”) and a Y direction (hereinafter also referred to as “second direction”), which is perpendicular to the X direction.

Each of the plurality of semiconductor chip regions 110 has a rectangular shape (here, a square shape). Each semiconductor chip region 110 includes a non-effective region 112 in each of two corner portions located at two ends of a side 110x, which runs along the X direction. The term “non-effective region” as used herein means a region in which a circuit device functioning as a circuit element or an element necessary for the circuit element to operate correctly is not placed. An element whose formation in the non-effective region 112 is allowed is accordingly a dummy pattern, an alignment mark, or other elements that do not cause a problem if broken or lost after dicing is finished.

The semiconductor chip region 110 minus the two non-effective regions 112 is an effective region 111. The term “effective region” as used herein means a region in which a circuit device functioning as a circuit element or an element necessary for the circuit element to operate correctly is placed.

The non-effective regions 112 are provided only at the two corner portions of the semiconductor chip region 110 that are described above, and not at the remaining two corner portions, which are accordingly a part of the effective region. A larger effective region can therefore be set than in Japanese Patent Application Laid-open No. 2009-99681, in which non-effective regions are provided at all four corners of each semiconductor chip region.

The side 110x of each semiconductor chip region 110 is on the same straight line as the sides 110x of a plurality of semiconductor chip regions 110 aligned in the same row as (adjacent to) the semiconductor chip region 110 of interest in the X direction.

The non-effective regions 112 are equally spaced from one another in the Y direction. Specifically, the non-effective regions 112 are provided closer to the side 110x (the lower side in FIG. 1) in any semiconductor chip region 110.

Each non-effective region 112 has a shape of a right triangle that has a longer side about the right angle along the Y direction and has a right-angled portion that matches with a corner portion of the semiconductor chip region 110.

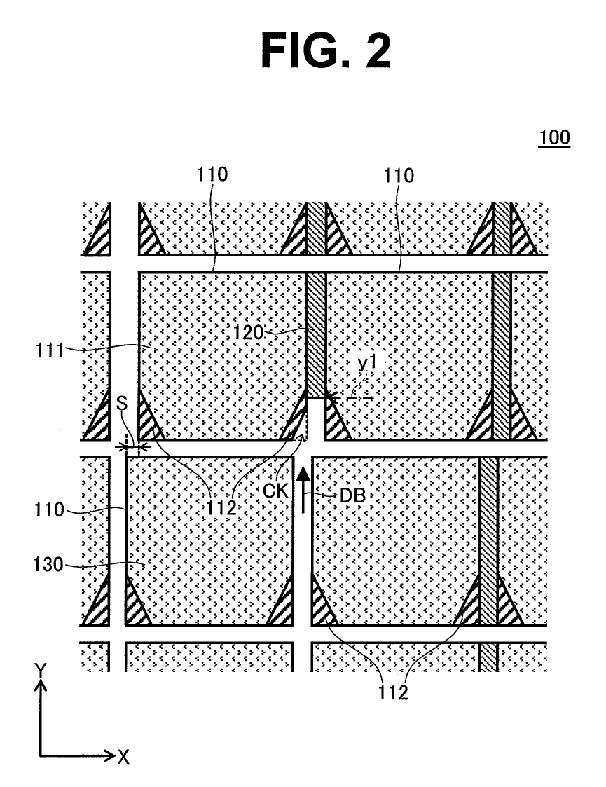

A step of dicing the semiconductor wafer 100 is described next with reference to FIG. 2. In FIG. 2, a first dicing step is complete and a second dicing step is in progress (cutting has progressed to a point indicated by the broken line arrow y1 in FIG. 2).

First, the semiconductor wafer 100 illustrated in FIG. 1 is set in a dicing apparatus (not shown).

Next, a dicing blade (not shown) divides the semiconductor wafer 100 into strips as the first dicing step, by dicing the semiconductor wafer 100 along the dicing lines 120 that run in the X direction out of the plurality of dicing lines 120.

The dicing blade subsequently divides the semiconductor wafer 100 into a plurality of individual semiconductor chips 130 as the second dicing step by dicing the semiconductor wafer 100 along the dicing lines 120 that run in the Y direction. The traveling direction of the dicing blade in the second dicing step is set to a direction facing the two corner portions at which the non-effective regions 112 are provided (the direction of the arrow DB in FIG. 2).

According to the first embodiment, chipping in the effective region 111 can be prevented in the manner described above even if a shift S occurs between the semiconductor chip regions 110 that are adjacent to each other in the Y direction after the first dicing step is finished as in the case illustrated in FIG. 11.

Specifically, the dicing blade advancing as indicated by the arrow DB bumps into one of the non-effective regions 112 and causes a crack CK in the non-effective region 112. However, the crack CK is contained within the non-effective region 112, and is kept from spreading to the effective region 111 and breaking wiring in the effective region 111 or otherwise affecting the circuit device.

Each non-effective region 112 in the first embodiment is shaped like a right triangle that has a longer side about the right angle along the Y direction as described above. Because the crack CK occurs along the traveling direction of the dicing blade (the Y direction) in the second dicing step, the non-effective region 112 does not need to have a length (width) in the X direction as long (wide) as that in the Y direction.

The effective region 111 can be set even larger by employing this shape in which the non-effective region 112 has a longer side about the right angle along the Y direction and is narrow in width in the X direction.

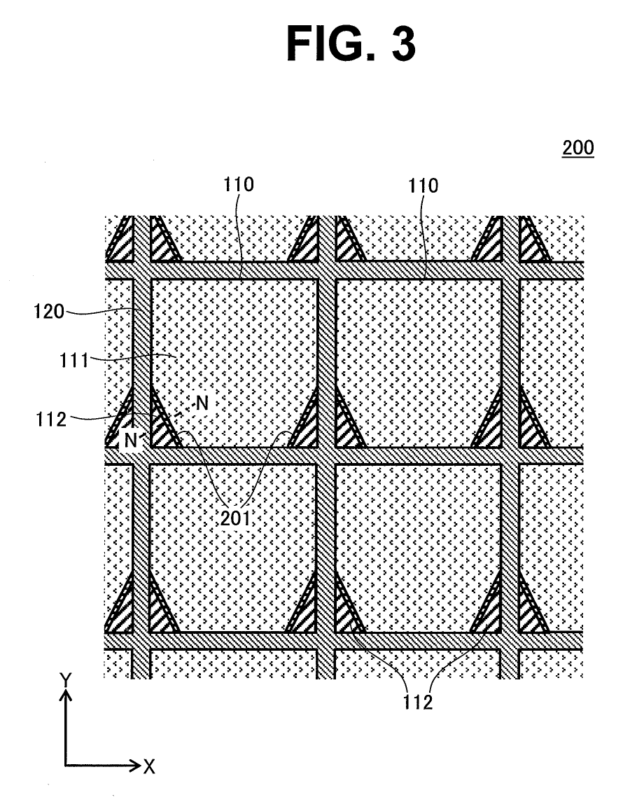

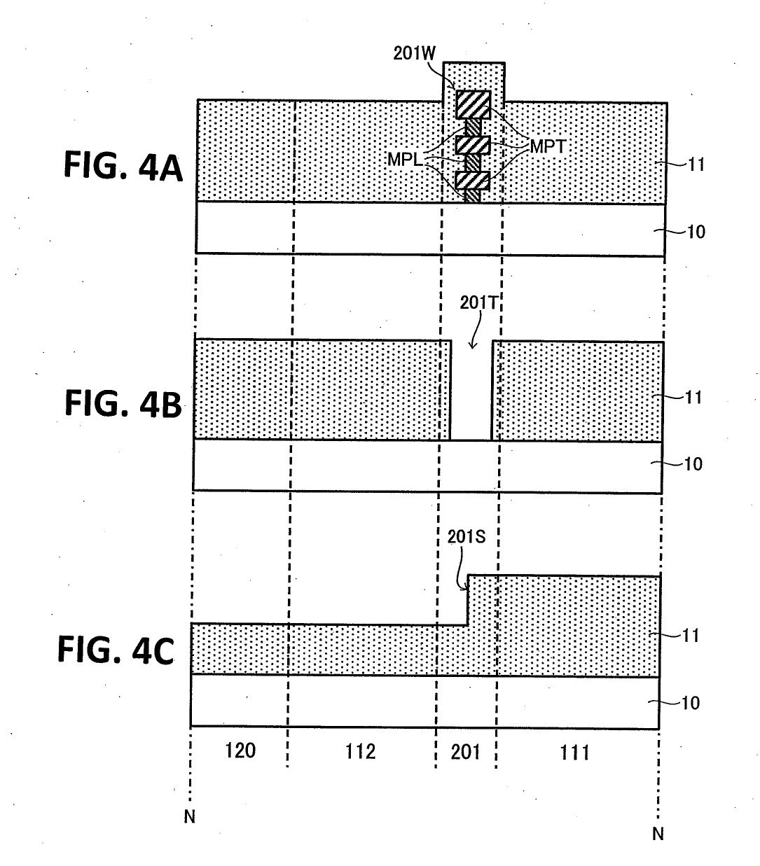

A second embodiment of the present invention is described next with reference to FIG. 3 and FIG. 4A to FIG. 4C.

FIG. 3 is a partial enlarged view of a semiconductor wafer 200 according to the second embodiment of the present invention.

Components of the semiconductor wafer 200 that are the same as those of the semiconductor wafer 100 illustrated in FIG. 1 are denoted by the same reference symbols in order to omit repetitive descriptions as appropriate.

The semiconductor wafer 200 includes crack stopper regions 201 in addition to the configuration of the semiconductor wafer 100. Each crack stopper region 201 is provided along the hypotenuse of one of the non-effective regions 112, that is, along each border portion between one non-effective region 112 and one effective region 111.

FIG. 4A to FIG. 4C are sectional views taken along the line N-N of FIG. 3 to illustrate specific configuration examples of each crack stopper region 201.

In the example of FIG. 4A, the crack stopper region 201 has a wall-like structure 201W. The wall-like structure 201W has a layered structure that is provided on a semiconductor substrate 10 and that includes a stack of metal plugs MPL and metal patterns MPT. The wall-like structure 201W is covered with an insulating film 11.

The crack stopper region 201 has a groove 201T in the example of FIG. 4B. The groove 201T is formed by etching the insulating film 11 on the semiconductor substrate 10.

The crack stopper region 201 has a step 201S in the example of FIG. 4C. The step 201S is formed by etching the insulating film 11 on the semiconductor substrate 10.

Chipping is more likely to occur when the semiconductor wafer is thinner and each semiconductor chip region is smaller in size. In such cases, a crack can be reliably prevented from spreading into the effective region 111 by providing the crack stopper region 201 as in the second embodiment.

The crack stopper region 201 is not limited to the configurations illustrated in FIG. 4A to FIG. 4C, and may have a structure that is a hybrid of the illustrated configurations or a different structure.

According to the second embodiment, a crack is prevented from reaching the effective region more reliably than in the first embodiment as described above. However, a simpler configuration that does not include the crack stopper regions 201 as in the first embodiment is preferred in view of the thickness of the semiconductor wafer and the size of each semiconductor chip region when the effective region 111 can be sufficiently protected from chipping without providing the crack stopper regions 201.

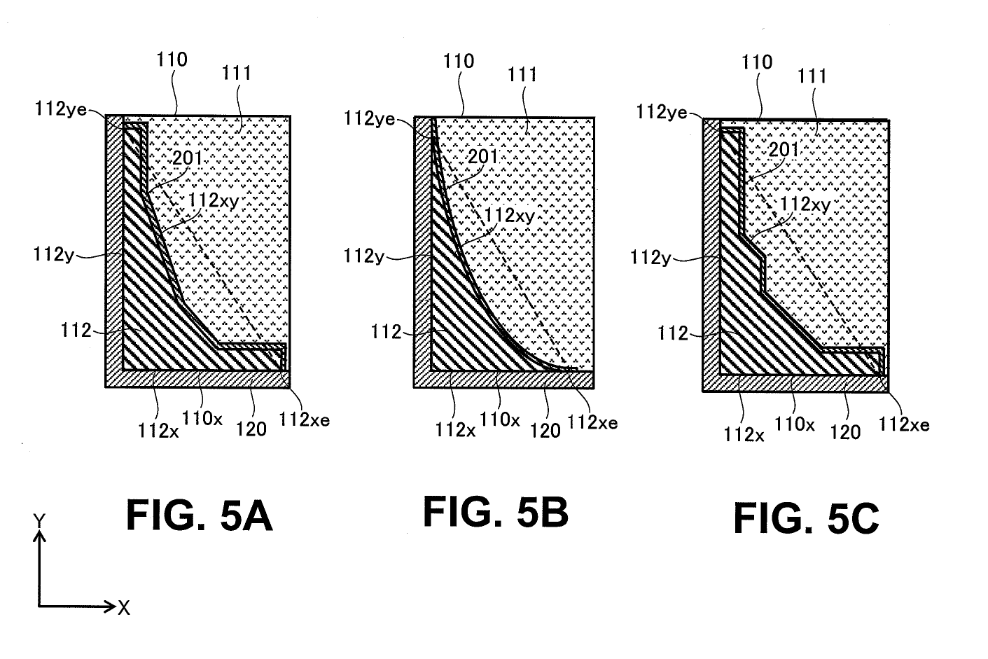

Another example of the non-effective regions 112 in the embodiments of the present invention is illustrated in FIG. 5A to FIG. 5C.

The non-effective regions 112 are each shaped like a right triangle that has a longer side about the right angle along the Y direction in the first embodiment and the second embodiment described above, but the shape is not limited thereto. The shape of each non-effective region 112 may be, for example, as illustrated in FIG. 5A to FIG. 5C.

The non-effective region 112 of FIG. 5A to FIG. 5C has a right-angled portion formed by a first straight line portion 112x and a second straight line portion 112y, which is longer than the first straight line portion 112x. The right-angled portion matches with a corner portion of the semiconductor chip region 110. The first straight line portion 112x is located along the side 110x, which runs along the X direction of the semiconductor chip region 110. The first straight line portion 112x has an end portion 112xe opposite from the right-angled portion, and the second straight line portion 112y has an end portion 112ye opposite from the right-angled portion. The end portion 112xe and the end portion 112ye are connected by a line 112xy, which is made up of a plurality of straight lines, or a curve 112xy.

The illustrated shape is smaller in area than a right triangle that is formed by a straight line (represented by a broken line in FIG. 5A to FIG. 5C) connecting the end portion 112xe and the end portion 112ye, the first straight line portion 112x, and the second straight line portion 112y.

The effective region 111 can be increased in area by giving each non-effective region 112 this shape, which is smaller in area than the right triangle.

While the case in which the crack stopper region 201 is provided along each border portion between one non-effective area 112 and one effective area 111 is illustrated in FIG. 5A to FIG. 5C, the crack stopper region 201 may be omitted as in the first embodiment.

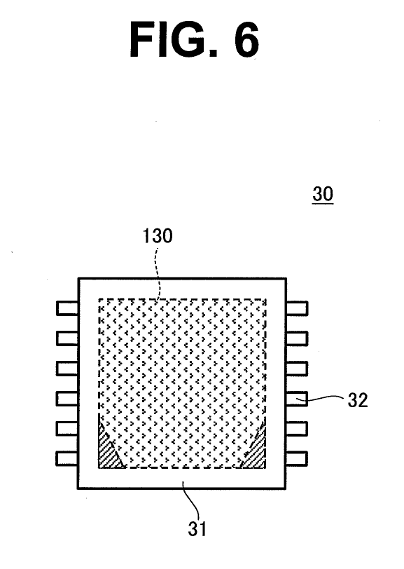

Each semiconductor chip 130 that is one of individual pieces created by dicing a semiconductor wafer in the manner described in the embodiments is mounted on a lead frame (not shown), which is connected to external terminals 32, and is sealed with a sealing resin 31 to be a semiconductor apparatus 30 as illustrated in FIG. 6.

The embodiments of the present invention have been described above, but the present invention is not limited to the above-mentioned embodiments, and it should be understood that various modifications can be made thereto without departing from the gist of the present invention.

For example, each semiconductor chip region, which has a square shape in the examples of the embodiments, may have an oblong rectangular shape.

The material of the semiconductor wafer (semiconductor substrate) is not limited as long as the wafer can be stuck onto dicing tape and diced into individual pieces by a dicing blade. For example, Si, SiC, GaN, or GaAs can be used as the semiconductor wafer.

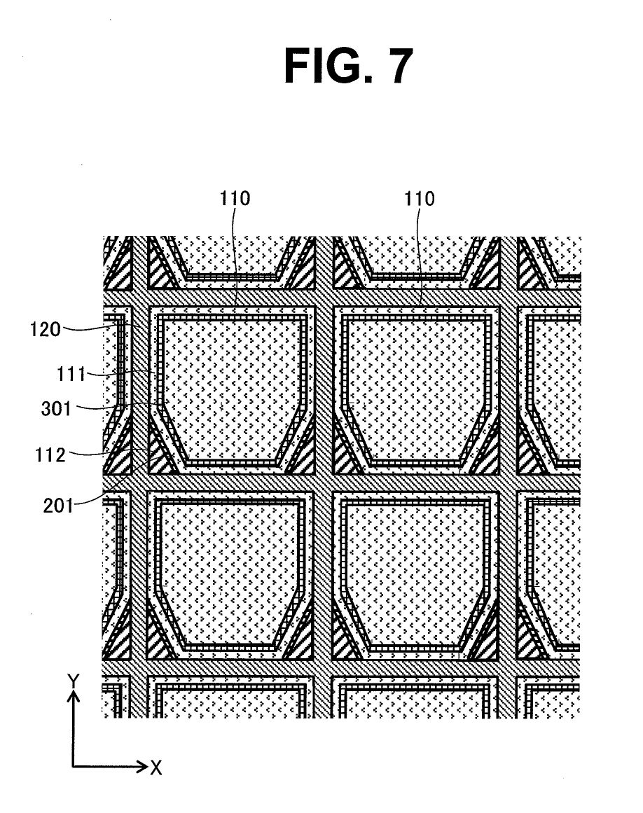

When each semiconductor chip region 110 in the present invention includes a seal ring 301 as illustrated in FIG. 7, the effective region 111 includes the seal ring 301. The seal ring is an element that must not be broken even after dicing in order to prevent the infiltration of moisture from outer peripheral side surfaces of the semiconductor chip, namely, an element necessary for a circuit element to operate correctly, and is therefore treated as a part of the effective region 111.

What is claimed is:

1. A semiconductor chip, comprising a principal surface having a shape of a rectangle having four sides,
the principal surface comprising:
non-effective regions in which no circuit device is placed, the non-effective regions being provided only at two corner portions that are located at two ends of one arbitrary side out of the four sides; and
an effective region in which a circuit device is placed, the effective region being provided in a remaining region other than the non-effective regions.

2. A semiconductor chip according to claim 1, wherein each of the non-effective regions has a shape of a right triangle that has a longer side about the right angle along a direction perpendicular to the one arbitrary side, and has a right-angled portion matching with one of the two corner portions.

3. A semiconductor chip according to claim 1, wherein each of the non-effective regions has a shape smaller in area than a right triangle that has a right-angled portion formed by a first straight line portion and a second straight line portion which is longer than the first straight line portion, and that is formed from a straight line connecting an end portion of the first straight line portion and an end portion of the second straight line portion, the first straight line portion, and the second straight line portion, the right-angled portion matching with one of the two corner portions, the first straight line portion being located along the one arbitrary side, the end portion of the first straight line portion being opposite from the right-angled portion, the end portion of the second straight line portion being opposite from the right-angled portion.

4. A semiconductor chip according to claim 1;
wherein each of the non-effective regions has a right-angled portion formed from a first straight line portion and a second straight line portion which is longer than the first straight line portion, the right-angled portion matching with one of the two corner portions, the first straight line portion being located along the one arbitrary side, and
wherein each of the non-effective regions has a shape smaller in area than a right triangle constructed by the first straight line portion, the second straight line portion, and a straight line connecting an end portion of the first straight line portion opposite to the right-angled portion and an end portion of the second straight line portion opposite to the right-angled portion.

5. A semiconductor chip according to claim 1, further comprising a crack stopper region provided along each border portion between the non-effective regions and the effective region.

6. A semiconductor chip according to claim 5, wherein the crack stopper region comprises one of a wall, a groove, and a step, which are formed in a surface of the semiconductor chip.

7. A semiconductor apparatus, comprising the semiconductor chip of claim 1, the semiconductor chip being sealed with resin.

8. A semiconductor wafer, comprising a plurality of semiconductor chip regions and a plurality of dicing lines which are alternated and aligned in a first direction and a second direction which is perpendicular to the first direction,
each of the plurality of semiconductor chip regions having a rectangular shape and comprising non-effective regions and an effective region, the non-effective regions being provided only at two corner portions that are located at two ends of one side along the first direction, the non-effective regions having no circuit device, the effective region being provided in a remaining region other than the non-effective regions, the effective region having a circuit device,
the one side of each of the plurality of semiconductor chip regions being on the same straight line as the one side of each of other semiconductor chip regions that are aligned in the same row as the each of the plurality of semiconductor chip regions in the first direction, and
the non-effective regions being equally spaced from one another in the second direction.

9. A semiconductor wafer according to claim 8, wherein each of the non-effective regions has a shape of a right triangle that has a longer side about the right angle along the second direction, and has a right-angled portion matching with one of the two corner portions.

10. A semiconductor chip according to claim 8;
wherein each of the non-effective regions has a right-angled portion formed from a first straight line portion in parallel to the first direction and a second straight line portion in parallel to the second direction, the second straight line portion being longer than the first straight line portion, the right-angled portion matching with one of the two corner portions, and
wherein each of the non-effective regions has a shape smaller in area than a right triangle constructed by the first straight line portion, the second straight line portion, and a straight line connecting an end portion of the first straight line portion opposite to the right-angled portion and an end portion of the second straight line portion opposite to the right-angled portion.

11. A semiconductor wafer according to claim 8, further comprising a crack stopper region provided along each border portion between the non-effective regions and the effective region.

12. A semiconductor wafer according to claim 11, wherein the crack stopper region comprises one of a wall, a groove, and a step which are formed in a surface of the semiconductor chip region.

13. A semiconductor wafer dicing method, comprising:
a step of preparing a semiconductor wafer on which a plurality of semiconductor chip regions and a plurality of dicing lines are alternated and aligned longitudinally and laterally;
a first dicing step of dicing the semiconductor wafer into strips along dicing lines that run in a first direction out of the plurality of dicing lines, by using a dicing blade; and
a second dicing step of dicing the semiconductor wafer into a plurality of individual semiconductor chips along dicing lines that run in a second direction perpendicular to the first direction out of the plurality of dicing lines, by using the dicing blade,
wherein each of the plurality of semiconductor chip regions has a rectangular shape and comprises non-effective regions and an effective region, the non-effective regions being provided only at two corner portions that face a traveling direction of the dicing blade in the second dicing step, the non-effective regions comprising no circuit device, the effective region being provided in a remaining region other than the non-effective regions, the effective region comprising a circuit device.

14. A semiconductor wafer dicing method according to claim 13, wherein each of the non-effective regions has a shape of a right triangle that has a longer side about the right angle along the second direction and has a right-angled portion matching with one of the two corner portions.

15. A semiconductor chip according to claim 13;
wherein each of the non-effective regions has a right-angled portion formed from a first straight line portion in parallel to the first direction and a second straight line portion in parallel to the second direction, the second straight line portion being longer than the first straight line portion, the right-angled portion matching with one of the two corner portions, and
wherein each of the non-effective regions has a shape smaller in area than a right triangle constructed by the first straight line portion, the second straight line portion, and a straight line connecting an end portion of the first straight line portion opposite to the right-angled portion and an end portion of the second straight line portion opposite to the right-angled portion.

16. A semiconductor wafer dicing method according to claim 13, wherein each of the plurality of semiconductor chip regions further comprises a crack stopper region provided along each border portion between the non-effective regions and the effective region.

17. A semiconductor wafer dicing method according to claim 16, wherein the crack stopper region comprises one of a wall, a groove, and a step, which are formed in a surface of the semiconductor chip region.
